(19) United States
(12) Patent Application Publication
(10) Pub. No.: US 2019/0279981 A1
(43) Pub. Date: Sep. 12, 2019

(54) VERTICAL TRANSPORT COMPLIMENTARY METAL-OXIDE-SEMICONDUCTOR WITH VARYING THRESHOLD VOLTAGES

(71) Applicant: International Business Machines Corporation, Armonk, NY (US)

(72) Inventors: Injo Ok, Loudonville, NY (US); Choonghyun Lee, Rensselaer, NY (US); Soon-Cheon Seo, Glenmont, NY (US); Seyoung Kim, Weschester, NY (US)

(21) Appl. No.: 15/913,528

(22) Filed: Mar. 6, 2018

(51) Int. Cl. H01L 27/092; H01L 29/78; H01L 21/8238

(52) U.S. Cl. CPC H01L 27/0922; H01L 21/823885; H01L 29/7827

(57) ABSTRACT

Techniques regarding a vertical transport complementary metal-oxide-semiconductor with a plurality of fin field effect transistors with varying threshold voltages are provided. For example, one or more embodiments can regard an apparatus, which can comprise a semiconductor substrate. The apparatus can also comprise a first conducting channel comprising a first concentration of a first element. The first conducting channel can extend from the semiconductor substrate, and the first element can be germanium. The apparatus can further comprise a second conducting channel comprising a second concentration of the first element. The second conducting channel can extend from the semiconductor substrate, and the first concentration can be greater than the second concentration. Moreover, the apparatus can comprise a metal dielectric gate adjacent to the first conducting channel and the second conducting channel.

### BACKGROUND

The subject disclosure relates to a vertical transport complimentary metal-oxide-semiconductor (“CMOS”), and more specifically, fin field effect transistors (“finFET”) with varying threshold voltages.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, apparatuses, and/or methods that can regard a vertical transport CMOS with a plurality of finFETs having varying threshold voltages are described.

According to an embodiment, an apparatus is provided. The apparatus can comprise a semiconductor substrate. The apparatus can also comprise a first conducting channel comprising a first concentration of a first element. The first conducting channel can extend from the semiconductor substrate, and the first element can be germanium. The apparatus can further comprise a second conducting channel comprising a second concentration of the first element. The second conducting channel can extend from the semiconductor substrate, and the first concentration can be greater than the second concentration. Moreover, the apparatus can comprise a metal dielectric gate adjacent to the first conducting channel and the second conducting channel.

According to another embodiment, a method is provided. The method can comprise forming a first conducting channel and a second conducting channel on a semiconductor substrate. The first conducting channel and the second conducting channel can comprise silicon-germanium. Also, a germanium oxide layer can be located on a surface of the first conducting channel. The method can also comprise annealing the first conducting channel to facilitate an oxidation between the silicon-germanium and the germanium oxide layer that can increase a concentration of germanium comprised within the first conducting channel. Further, the method can comprise depositing respective source terminals, respective drain terminals, and a metal dielectric gate adjacent to the first conducting channel and the second conducting channel to form a first fin field effect transistor and a second fin field effect transistor.

According to another embodiment, an apparatus is provided. The apparatus can comprise a semiconductor substrate. The apparatus can also comprise a first conducting channel comprising a first element. The first conducting channel can extend from the semiconductor substrate, and the first element can be germanium. The apparatus can further comprise a second conducting channel comprising a second element. The second conducting channel can extend from the semiconductor substrate. Also, the second element can be selected from a group consisting of periodic table group thirteen, periodic table group fourteen and periodic table group fifteen. Moreover, the apparatus can comprise a metal dielectric gate adjacent to the first conducting channel and the second conducting channel.

### BRIEF DESCRIPTION OF THE DRAWINGS

FIG. 1 illustrates a diagram of an example, non-limiting cross-sectional view of a vertical transport CMOS comprising a plurality of finFETs with various threshold voltages in accordance with one or more embodiments described herein.

FIG. 2A illustrates a diagram of an example, non-limiting cross-section view of a vertical transport CMOS during a first stage of manufacturing in accordance with one or more embodiments described herein.

FIG. 2B illustrates a diagram of an example, non-limiting cross-section view of a vertical transport CMOS during a second stage of manufacturing in accordance with one or more embodiments described herein.

FIG. 3A illustrates a diagram of an example, non-limiting cross-section view of a vertical transport CMOS during a third stage of manufacturing in accordance with one or more embodiments described herein.

FIG. 3B illustrates a diagram of an example, non-limiting cross-section view of a vertical transport CMOS during a fourth stage of manufacturing in accordance with one or more embodiments described herein.

FIG. 4A illustrates a diagram of an example, non-limiting cross-section view of a vertical transport CMOS during a fifth stage of manufacturing in accordance with one or more embodiments described herein.

FIG. 4B illustrates a diagram of an example, non-limiting cross-section view of a vertical transport CMOS during a sixth stage of manufacturing in accordance with one or more embodiments described herein.

FIG. 5A illustrates a diagram of an example, non-limiting cross-section view of a vertical transport CMOS during a seventh stage of manufacturing in accordance with one or more embodiments described herein.

FIG. 5B illustrates a diagram of an example, non-limiting cross-section view of a vertical transport CMOS during an eighth stage of manufacturing in accordance with one or more embodiments described herein.

FIG. 6A illustrates a diagram of an example, non-limiting cross-section view of a vertical transport CMOS during a ninth stage of manufacturing in accordance with one or more embodiments described herein.

FIG. 6B illustrates a diagram of an example, non-limiting cross-section view of a vertical transport CMOS during a tenth stage of manufacturing in accordance with one or more embodiments described herein.

FIG. 7A illustrates a diagram of an example, non-limiting cross-section view of a vertical transport CMOS during an eleventh stage of manufacturing in accordance with one or more embodiments described herein.

FIG. 7B illustrates a diagram of an example, non-limiting cross-section view of a vertical transport CMOS during a twelfth stage of manufacturing in accordance with one or more embodiments described herein.

FIG. 8A illustrates a diagram of an example, non-limiting cross-section view of a vertical transport CMOS during a thirteenth stage of manufacturing in accordance with one or more embodiments described herein.

FIG. 8B illustrates a diagram of an example, non-limiting cross-section view of a vertical transport CMOS during a fourteenth stage of manufacturing in accordance with one or more embodiments described herein.

FIG. 9A illustrates a diagram of an example, non-limiting cross-section view of a vertical transport CMOS during a fifteenth stage of manufacturing in accordance with one or more embodiments described herein.

FIG. 9B illustrates a diagram of an example, non-limiting cross-section view of a vertical transport CMOS during a sixteenth stage of manufacturing in accordance with one or more embodiments described herein.

FIG. 10A illustrates a diagram of an example, non-limiting cross-section view of a vertical transport CMOS during a seventeenth stage of manufacturing in accordance with one or more embodiments described herein.

FIG. 10B illustrates a diagram of an example, non-limiting cross-section view of a vertical transport CMOS during an eighteenth stage of manufacturing in accordance with one or more embodiments described herein.

FIG. 11A illustrates a diagram of an example, non-limiting cross-section view of a vertical transport CMOS during a nineteenth stage of manufacturing in accordance with one or more embodiments described herein.

FIG. 11B illustrates a diagram of an example, non-limiting cross-section view of a vertical transport CMOS during a twentieth stage of manufacturing in accordance with one or more embodiments described herein.

FIG. 12A illustrates a diagram of an example, non-limiting cross-section view of a vertical transport CMOS during a twenty-first stage of manufacturing in accordance with one or more embodiments described herein.

FIG. 12B illustrates a diagram of an example, non-limiting cross-section view of a vertical transport CMOS during a twenty-second stage of manufacturing in accordance with one or more embodiments described herein.

FIG. 13 illustrates a flow diagram of an example, non-limiting method that can facilitate manufacturing of a vertical transport CMOS comprising a plurality of FETs with varying threshold voltages in accordance with one or more embodiments described herein.

FIG. 14 illustrates a block diagram of an example, non-limiting operating environment in which one or more embodiments described herein can be facilitated.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Conventional strategies to offer varying threshold voltages on CMOS devices, such as finFETs, have relied on, for example: gate length modulation, channel doping, and/or work-function metal adjustment. However, each of these conventional strategies has numerous disadvantages. For example, gate length modulation offers a maximum of about 50 millivolts (mV) of threshold voltage modulation, and lithography methods needed to define different gate lengths can limit the device pitch; wherein threshold voltage adjustment on a narrow pitch vertical FET can require at least 5 nanometers (nm) of metal on each complimentary FET. In another example, channel doping can lead to random dopant fluctuations and/or mobility degradation. In a further example, using different dielectric constant metal stacks can cause process integration complexity (e.g., due to numerous required mask set and patterning processes, including wet reactive-ion etching).

Various embodiments described herein can regard a CMOS device comprising one or more devices (e.g., finFETs) with varying threshold voltages. For example, one or more embodiments described herein can regard achieving different threshold voltages across finFETs based, at least in part, on the use of different conductive materials comprised within the respective conducting channels. In another example, one or more embodiments described herein can regard achieving different threshold voltages across finFETs based, at least in part, on the use of the same conductive materials comprised within the respective conducting channels, but with different concentrations.

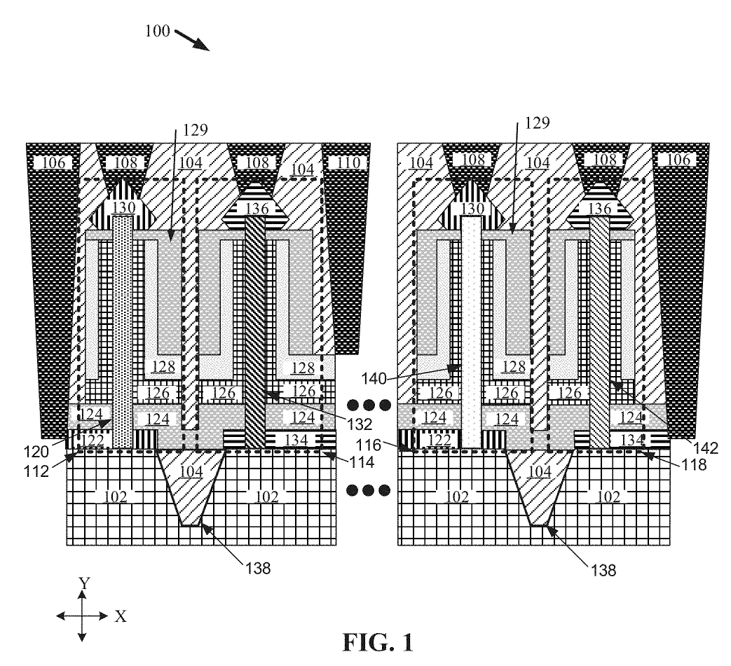

FIG. 1 illustrates a diagram of an example, non-limiting cross-sectional view of vertical transport CMOS 100 in accordance with one or more embodiments described herein. The cross-hatching and/or shading shown in FIG. 1 delineates common features and/or common materials described herein. The vertical transport CMOS 100 can comprise a semiconductor substrate 102, a plurality of finFETs, a dielectric layer 104, one or more bottom source and/or drain (“S/D”) contacts 106, on or more top S/D contacts 108 and/or one or more gate contacts 110. In one or more embodiments, the plurality of finFETs can have respective threshold voltages that are different from each other. For example, the various threshold voltages can be achieved via implementation of various conductive materials and/or various concentrations of said conductive materials.

The plurality of finFETs can be located adjacent to a semiconductor substrate 102. For example, the plurality of finFETs can be located on top of the semiconductor substrate 102 along a “Y” axis, as shown in FIG. 1. Example materials that can comprise the semiconductor substrate 102 can include, but are not limited to: silicon, germanium, silicon carbide, carbon doped silicon, compound semiconductors (e.g., comprising elements from periodic table groups III, IV, and/or V), a combination thereof, and/or the like. For instance, the semiconductor substrate 102 can be a bulk silicon wafer and/or a silicon-on-insulator (SOI) wafer. Additionally, the semiconductor substrate 102 can comprise electronic structures such as isolation wires (not shown). For example, the semiconductor substrate 102 can comprise silicon <111>. As used herein, the term “silicon <111>” can refer to a silicon wafer having a crystal orientation (111), as described using Miller indices (e.g., comprising atoms on three planes).

The plurality of finFETs can comprise, for example, four types of finFETs: a first finFET 112, a second finFET 114, a third finFET 116, and/or a fourth finFET 118. In one or more embodiments, the vertical transport CMOS 100 can comprise all four types of finFET. In various embodiments, the vertical transport CMOS 100 can comprise two or more types of finFET. Each type of finFET can comprise a respective conductive material and/or a respective concentration of conductive material; thereby each type of finFET can be characterized by a respective threshold voltage. For example, the respective threshold voltages of the finFETs shown in FIG. 1 can increase from left to right along the “X” axis. While FIG. 1 shows the four types of finFETs in a particular order, the architecture of the vertical transport CMOS 100 is not so limited. For instance, the vertical transport CMOS 100 can comprise finFETs of various types positioned in an order along the “X” axis other than the one shown in FIG. 1 (e.g., the first finFET 112, followed by the fourth finFET 118, followed by the third finFET 116, followed by the second finFET 114). In other words, one of ordinary skill in the art will recognize that the various types of finFETs described herein can be positioned along the semiconductor substrate 102 in a plethora of arrangements to facilitate a multitude of performance characteristics.

The first finFET 112 can comprise a first conducting channel 120. The first conducting channel 120 can extend from the semiconductor substrate 102 along the “Y” axis (e.g., vertically). The height (e.g., along the “Y” axis) and/or the width (e.g., along the “X” axis) of the first conducting channel 120 can be defined according to one or more desired performance characteristics of the first finFET 112 and/or the vertical transport CMOS 100. For example, the first conducting channel 120 can have a height (e.g., along the “Y” axis) greater than or equal to 20 nanometers (nm) and less than or equal to 100 nm. Also, the first conducting channel 120 can have a width (e.g., along the “X” axis) greater than or equal to 4 nm and less than or equal to 40 nm. The first conducting channel 120 can comprise a first conductive material with a first concentration. For example, the first conductive material can comprise one or more elements selected from the thirteenth group of the periodic table, the fourteenth group of the periodic table, and/or the fifteenth group of the periodic table. For instance, the first conducting channel 120 can comprise indium, gallium and/or arsenic. Additionally, the first concentration can regard the concentration of the one or more elements comprised within the first conducting channel 120. For example, wherein the first conducting channel 120 comprises indium, gallium and/or arsenic, the first concentration can regard a concentration of indium comprised within the first conducting channel 120. Further, in one or more embodiments, the first conductive material can be an epitaxial material. As used herein, the term “epitaxial material” can refer to a semiconductor material having substantially the same and/or similar crystalline characteristics (e.g., crystal orientation) as the substrate (e.g., semiconductor substrate 102) upon which the semiconductor material is formed. For example, an epitaxial material deposited on silicon <111> (e.g., as shown in FIG. 1) can exhibit the <111> orientation of the silicon.

The first finFET 112 can further comprise a first bottom S/D terminal 122. For example, the first bottom S/D terminal 122 can serve as a source terminal for the first finFET 112. In another example, the first bottom S/D terminal 122 can serve as a drain terminal for the first finFET 112. The first bottom S/D terminal 122 can be located adjacent to the first conducting channel 120 and/or the semiconductor substrate 102. Further, the first bottom S/D terminal 122 can be in direct contact with a plurality of sides of the first conducting channel 120. For example, as shown in FIG. 1, the first bottom S/D terminal 122 can be positioned on top of the semiconductor substrate 102 along the “Y” axis and/or adjacent to the first conducting channel 120 along the “X” axis. For instance, a first portion of the first bottom S/D terminal 122 can be position to the left of the first conducting channel 120 (e.g., as shown in FIG. 1), and another portion of the first bottom S/D terminal 122 can be position to the right of the first conducting channel 120 (e.g., as shown in FIG. 1). One of ordinary skill in the art will recognize that the thickness of the first bottom S/D terminal 122 can vary depending on a desired functionality. An example, non-limiting thickness of the first bottom S/D terminal 122 can be greater than or equal to 5 nm and less than or equal to 50 nm.

The first bottom S/D terminal 122 can be doped to induce a conductivity type, such as an n-type conductivity or a p-type conductivity. As used herein, the term “n-type” can refer to a contribution of free electrons to a semiconductor material by one or more impurities. Example semiconductor materials can include, but are not limited to, silicon (e.g., intrinsic silicon) and/or germanium (e.g., intrinsic germanium); and example, impurities that render n-type conductivity can include, but are not limited to: antimony, arsenic, phosphorus, a combination thereof, and/or the like. As used herein, the term “p-type” can refer to a deficiency of valence electrons in a semiconductor material due to the presence of one or more impurities. Example semiconductor materials can include, but are not limited to, silicon (e.g., intrinsic silicon) and/or germanium (e.g., intrinsic germanium); and example, impurities that render p-type conductivity can include, but are not limited to: boron, aluminum, gallium, indium, a combination thereof, and/or the like.

The first finFET 112 can have the same conductivity type as the first bottom S/D terminal 122. For example, wherein the first bottom S/D terminal 122 has n-type conductivity, the first finFET 112 can be an n-type finFET. In another example, wherein the first bottom S/D terminal 122 has p-type conductivity, the first finFET 112 can be a p-type finFET. In one or more embodiments, the first finFET 112 can be an n-type finFET, wherein the first bottom S/D terminal 122 can have n-type conductivity and comprise indium, arsenic and/or silicon (e.g., indium and/or arsenic impurities added to intrinsic silicon). Additionally, the first bottom S/D terminal 122 can be in contact with (e.g., adjacent to) a bottom S/D contact 106.

The first finFET 112 can further comprise a one or more spacer layers, which can comprise, for example, silicon nitride. A first spacer layer 124 from the one or more spacer layers can be positioned adjacent to the first bottom S/D terminal 122 and/or the first conducting channel 120. The first spacer layer 124 can be located between the first bottom S/D terminal 122 and a metal dielectric gate. Thus, the first spacer layer 124 can separate the first bottom S/D terminal 122 from the metal dielectric gate. As shown in FIG. 1, the first spacer layer 124 can be located on one side of the first bottom S/D terminal 122 and/or on a plurality of sides of the first bottom S/D terminal 122 (e.g., wherein the first spacer layer 124 extends around an end of the first bottom S/D terminal 122). Also shown in FIG. 1, a portion of the first spacer layer 124 can be positioned to the left of the first conducting channel 120 along the “X” axis, and another portion of the first spacer layer 124 can be positioned to the right of the first conducting channel 120 along the “X” axis.

Additionally, the first finFET 112 can comprise the metal dielectric gate located adjacent to the first conducting channel 120 and/or the first spacer layer 124. The metal dielectric gate can comprise a gate dielectric layer 126 and/or a metal layer 128. The gate dielectric layer 126 can be comprise a dielectric material, which can include, but is not limited to: an oxide, a nitride, a oxynitride, and/or the like. In one or more embodiments, the gate dielectric layer 126 can comprise a high-k dielectric material. As used herein, the term “high-k” refers to a material characterized by a dielectric constant (“k”) that is greater than the dielectric constant of silicon oxide (e.g., silicon dioxide) at room temperature. Example, high-k dielectric materials can include, but are not limited to: hafnium oxide (“HfO₂), zirconium oxide (“ZrO₂”), aluminum oxide (“Al₂O₃”), titanium oxide (“TiO₂”), lanthanum oxide (“La₂O₃”), strontium titanate (“SrTiO₃”), lanthanum aluminate (“LaAlO₃”), yttrium oxide (“Y₂O₃”), hafnium silicate, hafnium silicon oxynitride, a combination thereof, and/or the like.

The metal layer 128 can comprise a metal, which can include, but is not limited to: titanium, titanium nitride (“TiN”), titanium carbide, titanium aluminide (“TiAl”), titanium aluminum nitride (“TiAlN”), ruthenium, platinum, molybdenum, cobalt, tantalum nitride (“TaN”), hafnium nitride (“HfN”) combinations thereof, alloys thereof, and/or the like. In one or more embodiments, the metal layer 128 can be a p-type, thereby effectuating a p-type threshold voltage shift, or an n-type, thereby effectuating an n-type threshold voltage shift. As used herein, the term “threshold voltage” can refer to the lowest attainable gate voltage that can turn on a semiconductor device, such as, but not limited to, a finFET.

As shown in FIG. 1, the gate dielectric layer 126 can be positioned between the metal layer 128 and the first conducting channel 120. Further the gate dielectric layer 126 can be positioned between the metal layer 128 and the first spacer layer 124. Thus, the gate dielectric layer 126 can be located adjacent to the first conducting channel 120 and adjacent to the first spacer layer 124. For example, the gate dielectric layer 126 can have a vertical portion running adjacent to the conductive channel along the “Y” axis and/or a horizontal portion running adjacent to the first spacer layer 124 along the “X” axis. As shown in FIG. 1, the gate dielectric layer 126 can have a portion positioned to the left of the first conducting channel 120 along the “X” axis, and/or another portion positioned to the right of the first conducting channel 120 along the “X” axis.

The metal layer 128 can be positioned adjacent to the gate dielectric layer 126. For example, the metal layer 128 can have a vertical portion running adjacent to the vertical portion of the gate dielectric layer 126 along the “Y” axis. Further, the metal layer 128 can have a horizontal portion running adjacent to the horizontal portion of the gate dielectric layer 126 along the “X” axis.

The one or more spacer layers can further comprise a second spacer layer 129 located adjacent to the metal dielectric gate (e.g., the gate dielectric layer 126 and/or the metal layer 128). For example, the second spacer layer 129 can be positioned on one or more sides of the metal dielectric gate such that the metal dielectric gate is located between the first spacer layer 124 and the second spacer layer 129. For instance, the second spacer layer 129 can have a vertical portion running adjacent to the vertical portion of the metal layer 128 along the “Y” axis. Additionally, the second spacer layer 129 can have a horizontal portion running adjacent to an end of the metal dielectric gate along the “X” axis. The second spacer layer 129 can comprise the same material as the first spacer layer 124.

In addition, the first finFET 112 can comprise a first top S/D terminal 130. For example, the first top S/D terminal 130 can serve as a source terminal for the first finFET 112. In another example, the first top S/D terminal 130 can serve as a drain terminal for the first finFET 112. The first top S/D terminal 130 can be located adjacent to the first conducting channel 120 and/or the second spacer layer 129. For example, the first top S/D terminal 130 can be adjacent (e.g., in direct contact with) one or more sides of the first conducting channel 120. Further, the first top S/D terminal 130 can be located on top the second spacer layer 129 such that the second spacer layer 129 is located between the first top S/D terminal 130 and an end of the metal dielectric gate.

In one or more embodiments, the first top S/D terminal 130 of the first finFET 112 can comprise the same material as the bottom S/D terminal 122 of the first finFET 112. Also, the first top S/D terminal 130 of the first finFET 112 can have the same conductivity type as the first bottom S/D terminal 122 of the first finFET 112. For example, wherein the first bottom S/D terminal 122 has n-type conductivity and comprises indium, arsenic and/or silicon (e.g., indium and/or arsenic impurities added to intrinsic silicon), the first top S/D terminal 130 can also have n-type conductivity and comprise indium, arsenic and/or silicon (e.g., indium and/or arsenic impurities added to intrinsic silicon). Additionally, the first top S/D terminal 130 can be in contact with (e.g., adjacent to) a top S/D contact 108. Furthermore, the first finFET 112 can be encapsulated by the dielectric layer 104, such as silicon oxide (e.g., silicon dioxide).

The second finFET 114 can comprise the same structural features described herein with regard to the first finFET 112. For example, the second finFET 114 can comprise the first spacer layer 124, the metal dielectric gate (e.g., gate dielectric layer 126 and/or metal layer 128, and/or the second spacer layer 129. Further, the second finFET 114 can also be encapsulated by the dielectric layer 104. However, the second finFET 114 can exhibit a different threshold voltage than the first finFET 112 due, at least in part, to a different conducting channel.

The second conducting channel 132 can comprise a second conductive material, other than the first conductive material, with a second concentration. For example, the second finFET 114 can comprise a second conducting channel 132, which can comprise a different conducting material than the first finFET 112. For instance, wherein the first conducting channel 120 comprises a conducting material other than germanium (e.g., indium, gallium and/or arsenic), the second conducting channel 132 can comprise silicon-germanium. Further, the second concentration can regard a concentration of germanium comprised within the second conducting channel 132.

Similar to the first conducting channel 120, the second conducting channel 132 can extend from the semiconductor substrate 102 along the “Y” axis (e.g., vertically). The height (e.g., along the “Y” axis) and/or the width (e.g., along the “X” axis) of the second conducting channel 132 can be defined according to one or more desired performance characteristics of the second finFET 114 and/or the vertical transport CMOS 100. For example, the second conducting channel 132 can have a height (e.g., along the “Y” axis) greater than or equal to 20 nm and less than or equal to 100 nm. Also, the second conducting channel 132 can have a width (e.g., along the “X” axis) greater than or equal to 4 nm and less than or equal to 40 nm. In one or more embodiments, the second conducting channel 132 can have the same, and/or substantially similar, dimensions (e.g., height and/or width) as the first conducting channel 120. Further, in one or more embodiments, the second conductive material can be an epitaxial material.

Further, the second finFET 114 can comprise a second bottom S/D terminal 134 and/or a second top S/D terminal 136. For example, the second bottom S/D terminal 134 can serve as a source terminal for the second finFET 114. In another example, the second bottom S/D terminal 134 can serve as a drain terminal for the second finFET 114. The second bottom S/D terminal 134 can be located adjacent to the second conducting channel 132 and/or the semiconductor substrate 102. Further, the second bottom S/D terminal 134 can be in direct contact with a plurality of sides of the second conducting channel 132. For example, as shown in FIG. 1, the second bottom S/D terminal 134 can be positioned on top of the semiconductor substrate 102 along the “Y” axis and/or adjacent to the second conducting channel 132 along the “X” axis. For instance, a first portion of the second bottom S/D terminal 134 can be position to the left of the second conducting channel 132 (e.g., as shown in FIG. 1), and another portion of the second bottom S/D terminal 134 can be position to the right of the second conducting channel 132 (e.g., as shown in FIG. 1). One of ordinary skill in the art will recognize that the thickness of the second bottom S/D terminal 134 can vary depending on a desired functionality. An example, non-limiting thickness of the second bottom S/D terminal 134 can be greater than or equal to 5 nm and less than or equal to 50 nm.

The second bottom S/D terminal 134 can be doped to induce a conductivity type, such as an n-type conductivity or a p-type conductivity. In one or more embodiments, the second bottom S/D terminal 134 can be doped to compliment the first bottom S/D terminal 122. Thus, wherein the first bottom S/D terminal 122 has n-type conductivity, the second bottom S/D terminal 134 can have p-type conductivity and vise versa. The second finFET 114 can have the same conductivity type as the second bottom S/D terminal 134. For example, wherein the second bottom S/D terminal 134 has p-type conductivity, the second finFET 114 can be a p-type finFET. In one or more embodiments, the second finFET 114 can be a p-type finFET, wherein the second bottom S/D terminal 134 can have p-type conductivity and comprise silicon-germanium (e.g., germanium impurities added to intrinsic silicon). Additionally, the second bottom S/D terminal 134 can be in contact with (e.g., adjacent to) a bottom S/D contact 106.

The second top S/D terminal 136 can serve as a source terminal for the second finFET 114. In another example, the second top S/D terminal 136 can serve as a drain terminal for the second finFET 114. The second top S/D terminal 136 can be located adjacent to the second conducting channel 132 and/or the second spacer layer 129. For example, the second top S/D terminal 136 can be adjacent (e.g., in direct contact with) one or more sides of the second conducting channel 132. Further, the second top S/D terminal 136 can be located on top the second spacer layer 129 such that the second spacer layer 129 is located between the second top S/D terminal 136 and an end of the metal dielectric gate.

In one or more embodiments, the second top S/D terminal 136 of the second finFET 114 can comprise the same material as the second bottom S/D terminal 134 of the second finFET 114. Also, the second top S/D terminal 136 of the second finFET 114 can have the same conductivity type as the second bottom S/D terminal 134 of the second finFET 114. For example, wherein the second bottom S/D terminal 134 has p-type conductivity and comprises silicon-germanium (e.g., germanium impurities added to intrinsic silicon), the second top S/D terminal 136 can also have p-type conductivity and comprise silicon-germanium (e.g., germanium impurities added to intrinsic silicon). Additionally, the second top S/D terminal 136 can be in contact with (e.g., adjacent to) a top S/D contact 108.

As shown in FIG. 1, shallow trench isolation (“STI”) can be utilized to separate adjacent finFETs (e.g., first finFET 112 and/or second finFET 114) along the “X” axis. One or more shallow trenches 138 are delineated in FIG. 1 with bold lines. The one or more shallow trenches 138 can extend into the semiconductor substrate 102 and be filled with the dielectric layer 104. Additionally, as shown in FIG. 1, the dielectric layer 104 can extend through the second spacer layer 129 and/or the metal dielectric gate (e.g., the metal layer 128 and/or the gate dielectric layer 126) at positions between adjacent finFETs (e.g., first finFET 112 and/or second finFET 114). Thereby, the dielectric layer 104 can separate portions of the metal dielectric gate comprised within one finFET (e.g., first finFET 112) from portions of the metal dielectric gate comprised within another finFET (e.g., second finFET 114). Furthermore, the dielectric layer 104 can be positioned between the metal dielectric gate and one or more S/D contacts (e.g., one or more bottom S/D contacts 106).

The third finFET 116 can comprise the same structural features described herein with regard to the first finFET 112. For example, the third finFET 116 can comprise the first spacer layer 124, the metal dielectric gate (e.g., gate dielectric layer 126 and/or metal layer 128, the second spacer layer 129, the first bottom S/D terminal 122, and/or the first top S/D terminal 130. Further, the third finFET 116 can also be encapsulated by the dielectric layer 104. However, the third finFET 116 can exhibit a different threshold voltage than the first finFET 112 due, at least in part, to a different conducting channel.

The third finFET 116 can comprise a third conducting channel 140, which can comprise the first conductive material (e.g., as comprised within the first conducting channel 120) along with a third concentration. The third conducting channel 140 can be characterized by a third concentration of the first conductive material that is different than the first concentration of the first conductive material, which characterizes the first conducting channel 120. For example, the first concentration can be higher than the third concentration. For instance, the first conducting channel 120 can comprise indium, gallium and/or arsenic with a first concentration of 53 percent indium; whereas the third conducting channel 140 can comprise indium, gallium and/or arsenic with a third concentration of 20 percent indium. The difference in indium concentration between the first conducting channel 120 and/or the third conducting channel 140 can directly result in a difference in threshold voltage between the first finFET 112 and/or the third finFET 116. The threshold voltage of the first finFET 112 can be lower than the threshold voltage of the third finFET 116 in correlation with the first finFET 112 having a higher concentration of the first conductive material than the third finFET 116.

Similar to the first conducting channel 120, the third conducting channel 140 can extend from the semiconductor substrate 102 along the “Y” axis (e.g., vertically). The height (e.g., along the “Y” axis) and/or the width (e.g., along the “X” axis) of the third conducting channel 140 can be defined according to one or more desired performance characteristics of the third finFET 116 and/or the vertical transport CMOS 100. For example, the third conducting channel 140 can have a height (e.g., along the “Y” axis) greater than or equal to 20 nm and less than or equal to 100 nm. Also, the third conducting channel 140 can have a width (e.g., along the “X” axis) greater than or equal to 4 nm and less than or equal to 40 nm. In one or more embodiments, the third conducting channel 140 can have the same, and/or substantially similar, dimensions (e.g., height and/or width) as the first conducting channel 120.

In one or more embodiments, the third finFET 116 can have the same conductivity type as the first finFET 112. For example, wherein the first finFET 112 is an n-type finFET, the third finFET 116 can also be an n-type finFET. For instance, the third finFET 116 can comprise n-type first bottom S/D terminals 122 and/or n-type first top S/D terminals 130.

The fourth finFET 118 can comprise the same structural features described herein with regard to the second finFET 114. For example, the fourth finFET 118 can comprise the first spacer layer 124, the metal dielectric gate (e.g., gate dielectric layer 126 and/or metal layer 128, the second spacer layer 129, the second bottom S/D terminal 134, and/or the second top S/D terminal 136. Further, the fourth finFET 118 can also be encapsulated by the dielectric layer 104. However, the fourth finFET 118 can exhibit a different threshold voltage than the second finFET 114 due, at least in part, to a different conducting channel.

The fourth finFET 118 can comprise a fourth conducting channel 142, which can comprise the second conductive material (e.g., as comprised within the second conducting channel 132) along with a fourth concentration. The fourth conducting channel 142 can be characterized by a fourth concentration of the second conductive material that is different than the second concentration of the second conductive material, which characterizes the second conducting channel 132. For example, the second concentration can be higher than the fourth concentration. For instance, the second conducting channel 132 can comprise silicon-germanium with a second concentration of 40 percent germanium; whereas the fourth conducting channel 142 can comprise silicon-germanium with a fourth concentration of 20 percent germanium. The difference in germanium concentration between the second conducting channel 132 and/or the fourth conducting channel 142 can directly result in a difference in threshold voltage between the second finFET 114 and/or the fourth finFET 118. The threshold voltage of the second finFET 114 can be lower than the threshold voltage of the fourth finFET 118 in correlation with the second finFET 114 having a higher concentration of the second conductive material than the fourth finFET 118.

Similar to the second conducting channel 132, the fourth conducting channel 142 can extend from the semiconductor substrate 102 along the “Y” axis (e.g., vertically). The height (e.g., along the “Y” axis) and/or the width (e.g., along the “X” axis) of the fourth conducting channel 142 can be defined according to one or more desired performance characteristics of the fourth finFET 118 and/or the vertical transport CMOS 100. For example, the fourth conducting channel 142 can have a height (e.g., along the “Y” axis) greater than or equal to 20 nm and less than or equal to 100 nm. Also, the fourth conducting channel 142 can have a width (e.g., along the “X” axis) greater than or equal to 4 nm and less than or equal to 40 nm. In one or more embodiments, the fourth conducting channel 142 can have the same, and/or substantially similar, dimensions (e.g., height and/or width) as the second conducting channel 132.

In one or more embodiments, the fourth finFET 118 can have the same conductivity type as the second finFET 114. For example, wherein the second finFET 114 is a p-type finFET, the fourth finFET 118 can also be a p-type finFET. For instance, the fourth finFET 118 can comprise p-type second bottom S/D terminals 134 and/or p-type second top S/D terminals 136. Furthermore, the third finFET 116 and the fourth finFET 118 can exhibit different threshold voltages due at least in part to the different conductive material comprised within the third conducting channel 140 and/or the fourth conducting channel 142. For example, the threshold voltage of the fourth finFET 118 can be greater than the threshold voltage of the third finFET 116.

In various embodiments, the finFETs shown in FIG. 1 can be characterized by increasing threshold voltages from left to right along the “X” axis. For example, the fourth finFET 118 can exhibit a regular threshold voltage (“RVT”) greater than the third finFET's 116 threshold voltage. The third finFET's 116 threshold voltage can be greater than the second finFET's 114 threshold voltage. Further, the second finFET's 114 threshold voltage can be greater than the first finFET's 112 threshold voltage, which can be characterized as a super low threshold voltage (“SLVT”). Exemplary, non-limiting, threshold voltages for the first finFET 112 can be greater than or equal to 0.01 volts (V) and less than or equal to 0.1 V. Exemplary, non-limiting, threshold voltages for the second finFET 114 can be greater than or equal to 0.1 V and less than or equal to 1 V. Exemplary, non-limiting, threshold voltages for the third finFET 116 can be greater than or equal to 0.01 V and less than or equal to 0.1 V. Exemplary, non-limiting, threshold voltages for the fourth finFET 118 can be greater than or equal to 0.1 V and less than or equal to 1 V.

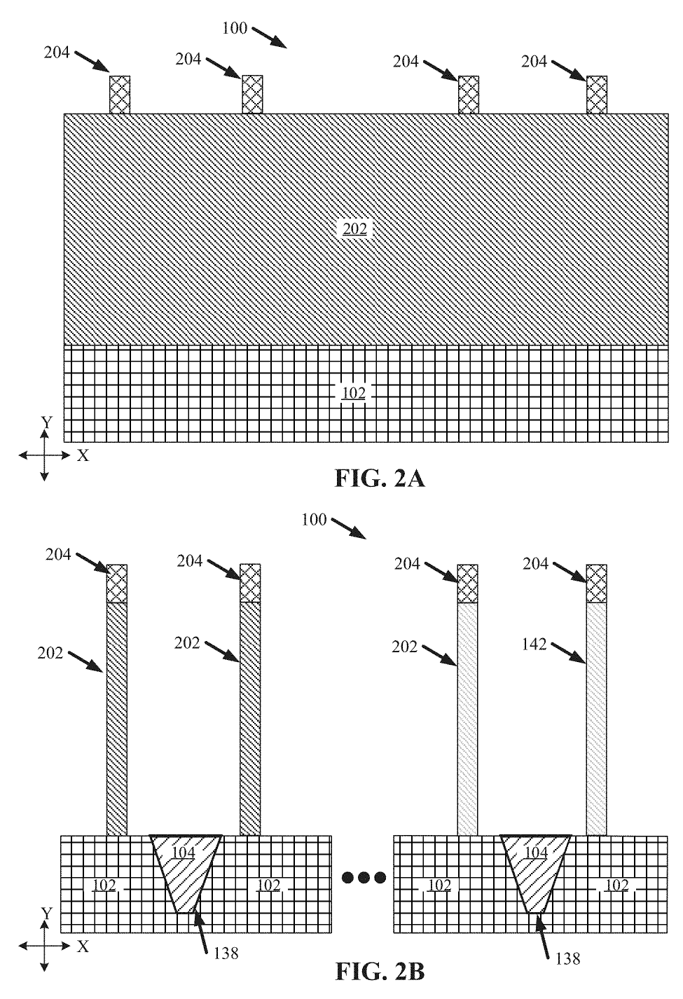

FIG. 2A illustrates a diagram of an example, non-limiting cross-sectional view of the vertical transport CMOS 100 during a first stage of manufacturing in accordance with one or more embodiments described herein. Repetitive description of like elements employed in other embodiments described herein is omitted for sake of brevity.

As shown in FIG. 2A, a conductive layer 202 can be deposited and/or grown adjacent (e.g., on top of) the semiconductor substrate 102. The conductive layer 202 can comprise the second conductive material having the fourth concentration. Thus, the conductive layer 202 can have the same composition as the fourth conducting channel 142 (e.g., as delineated in FIG. 2 by the common cross-hatching). For example, the conductive layer 202 can be an epitaxial material comprising silicon-germanium (e.g., with a concentration of 20% germanium). In one or more embodiments, the conductive layer 202 can be deposited and/or grown onto the semiconductor substrate 102 via, for example, chemical vapor deposition (“CVD”).

Additionally, a hardmask layer 204 can be patterned onto the conductive layer 202. The hardmask layer 204 can be a hydrofluoric acid resistant material such as, but not limited to: silicon boron carbon nitride (“SiBCN”), silicon carbon nitride (“SiCN”), a combination thereof, and/or the like. For example, the hardmask layer 204 can be patterned onto the conductive layer 202 using photolithography techniques. The hardmask layer 204 can define one or more locations for one or more conducting channels (e.g., first conducting channel 120, second conducting channel 132, third conducting channel 140, and/or fourth conducting channel 142).

FIG. 2B illustrates a diagram of an example, non-limiting cross-sectional view of the vertical transport CMOS 100 during a second stage of manufacturing in accordance with one or more embodiments described herein. Repetitive description of like elements employed in other embodiments described herein is omitted for sake of brevity.

As shown in FIG. 2B, portions of the conductive layer 202 that are not protected by the hardmask layer 204 can be removed via a deep etching process to shape one or more conducting channels. For example, the fourth conducting channel 142 can be shaped via the etching process, which can comprise, for example, reactive-ion etching (“RIE”) technology. In other words, exposed regions of the conductive layer 202 can be subjected to RIE. Additionally, one or more shallow trenches 138 (e.g., as delineated by bold lines in FIG. 2B) can be formed within the semiconductor substrate 102. The one or more shallow trenches 138 can be formed, for example, via a shallow etching process such as RIE. Further, the one or more shallow trenches 138 can be filled with the dielectric layer 104 (e.g., silicon oxide).

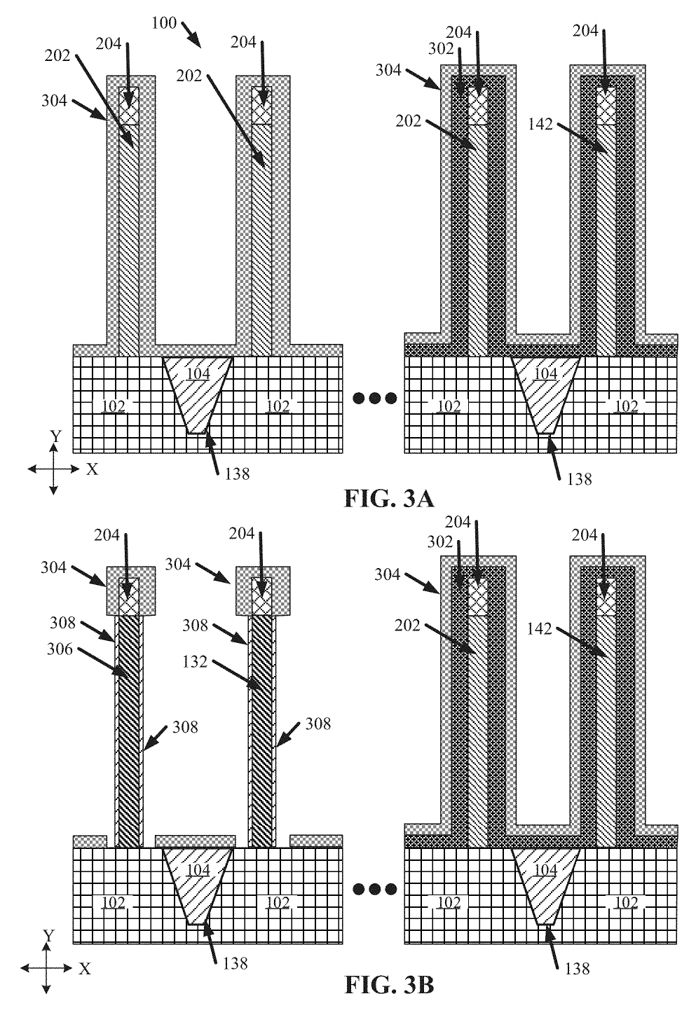

FIG. 3A illustrates a diagram of an example, non-limiting cross-sectional view of the vertical transport CMOS 100 during a third stage of manufacturing in accordance with one or more embodiments described herein. Repetitive description of like elements employed in other embodiments described herein is omitted for sake of brevity.

As shown in FIG. 3A, one or more conducting channels comprising the conductive layer 202 (e.g., including fourth conducting channel 142) can be capped with a protective layer 302 such as, but not limited to, silicon nitride. For example, the protective layer 302 can be deposited over one or more conducting channels comprising the conductive layer 202 (e.g., including fourth conducting channel 142), one or more shallow trenches 138, and/or one or more portions of the semiconductor substrate 102. The protective layer 302 can be deposited via a deposition process; which can include, but is not limited to: sputtering, evaporation, CVD, atomic layer deposition (“ALD”), a combination thereof, and/or the like. The protective layer 302 can have an exemplary, non-limiting, thickness greater than or equal to 2 nm and less than or equal to 20 nm.

After depositing the protective layer 302, a germanium oxide (e.g., germanium dioxide “GeO₂”) layer 304 can be blanket deposited over the vertical transport CMOS 100. For example, the germanium oxide layer 304 can be deposited over the protective layer 302 and any features of the vertical transport CMOS 100 not protected by the protective layer 302 (e.g., one or more portions of the hardmask layer 204, one or more conducting channels, the semiconductor substrate 102, and/or one or more shallow trenches 138). The germanium oxide layer 304 can have an exemplary, non-limiting, thickness greater than or equal to 1 nm and less than or equal to 10 nm.

FIG. 3B illustrates a diagram of an example, non-limiting cross-sectional view of the vertical transport CMOS 100 during a fourth stage of manufacturing in accordance with one or more embodiments described herein. Repetitive description of like elements employed in other embodiments described herein is omitted for sake of brevity.

At the fourth stage of manufacturing the vertical transport CMOS 100 can be subject to an annealing process, such as spike annealing. The annealing (e.g., spike annealing) can be conducted in an atmosphere comprising an inert gas, such as a nitrogen gas atmosphere. Further, the annealing can be performed at a temperature greater than or equal to 500 degrees Celsius (° C.) and less than or equal to 900° C. (e.g., 600° C.).

As shown in FIG. 3B, the annealing can cause conductive layer 202 (e.g., comprising silicon-germanium) to react with the germanium oxide layer 304 to form one or more concentrated conductive layers 306 and/or one or more silicon dioxide layers 308. The one or more concentrated conductive layers 306 can comprise the first conductive material (e.g., silicon-germanium) with the second concentration. In other words, the one or more concentrated conductive layers 306 can be characterized by higher concentrations of germanium than the conductive layer 202. By increasing the concentration of germanium, the annealing process can form the second conducting channel 132. For example, the second conducting channel 132 can comprise a silicon-germanium material with a concentration of 40 percent germanium.

The one or more silicon dioxide layers 308 can be located adjacent to the one or more concentrated conductive layers 306 (e.g., such as second conducting channel 132). For example, respective concentrated conductive layers 306 (e.g., such as second conducting channel 132) can be located between silicon dioxide layers 308 along the “X” axis, wherein each concentrated conductive layer 306 can be located adjacent to two silicon dioxide layers 308. The thickness of the one or more silicon dioxide layers 308 can be substantially similar to the thickness of the germanium oxide layer 304.

The annealing can facilitate an oxidation reaction between the one or more exposed portions of the conductive layer 202 and the germanium oxide layer 304, wherein silicon in the one or more exposed portions of the conductive layer 202 is oxidized to form the one or more silicon dioxide layers 308. For example, the oxidation reaction can be characterized by the following formula:

Si+Ge+2GeO₂→Ge+2GeO+SiO₂

The germanium product can be comprised within the one or more concentrated conductive layers 306 (e.g., such as second conducting channel 132), the germanium oxide product can be a volatile species, and/or the silicon dioxide product can form the one or more silicon dioxide layers 308. However, portions of the germanium oxide layer 304 that were not in contact with the one or more exposed portions of the conductive layer 202 can remain unreacted. For example, portions of the germanium oxide layer 304 adjacent to the one or more hardmask layers 204, the dielectric layer 104, and/or the semiconductor substrate 102 can remain unreacted.

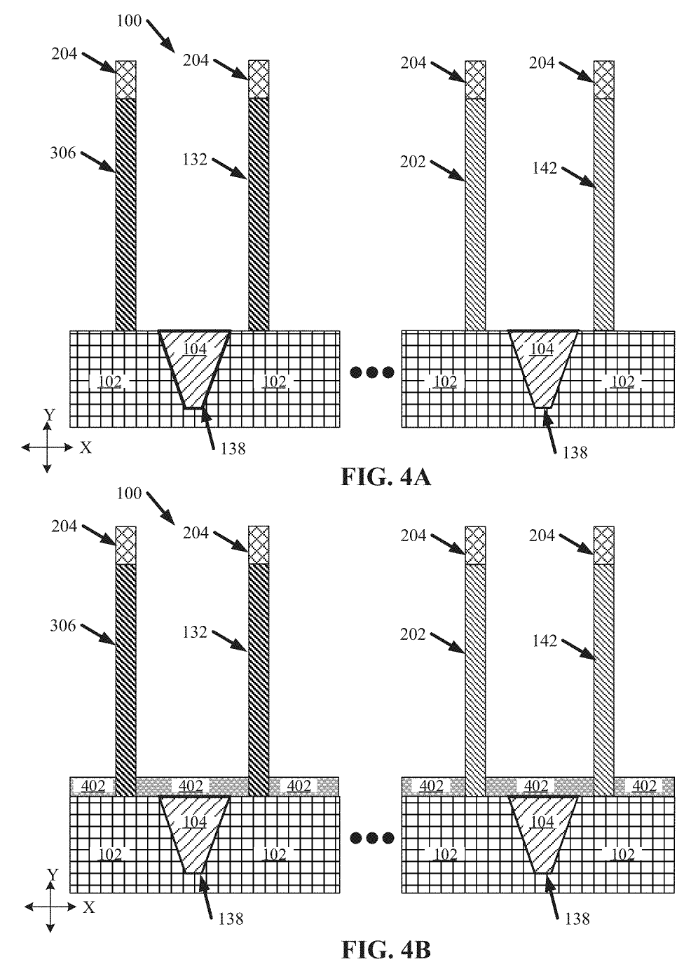

FIG. 4A illustrates a diagram of an example, non-limiting cross-sectional view of the vertical transport CMOS 100 during a fifth stage of manufacturing in accordance with one or more embodiments described herein. Repetitive description of like elements employed in other embodiments described herein is omitted for sake of brevity. As shown in FIG. 4A, the residual germanium oxide layer 304, the one or more silicon dioxide layers 308, and/or the protective layer 302 can be stripped from the vertical transport CMOS 100.

FIG. 4B illustrates a diagram of an example, non-limiting cross-sectional view of the vertical transport CMOS 100 during a sixth stage of manufacturing in accordance with one or more embodiments described herein. Repetitive description of like elements employed in other embodiments described herein is omitted for sake of brevity.

As shown in FIG. 4B, one or more third spacer layers 402 from the one or more spacer layers can be deposited adjacent (e.g., onto) the semiconductor substrate 102 and/or adjacent to the one or more conducting channels (e.g., the second conducting channel 132 and/or the fourth conducting channel 142). For example, high-density plasma CVD (“HDP CVD”) can be utilized in conjunction with RIE techniques to have bottom thick deposition, wherein the one or more third spacer layers 402 are formed only at the base of the one or more conducting channels (e.g., the second conducting channel 132 and/or the fourth conducting channel 142), as shown in FIG. 4B. The one or more third spacer layers 402 can have the same composition as the one or more spacer layers described herein with regard to FIG. 1 (e.g., as delineated by the common cross-hatching). The one or more third spacer layers 402 can serve to preserve the location of the one or more conducting channels and/or facilitate alignment of the one or more first bottom S/D terminals 122 and/or the one or more second bottom S/D terminals 134.

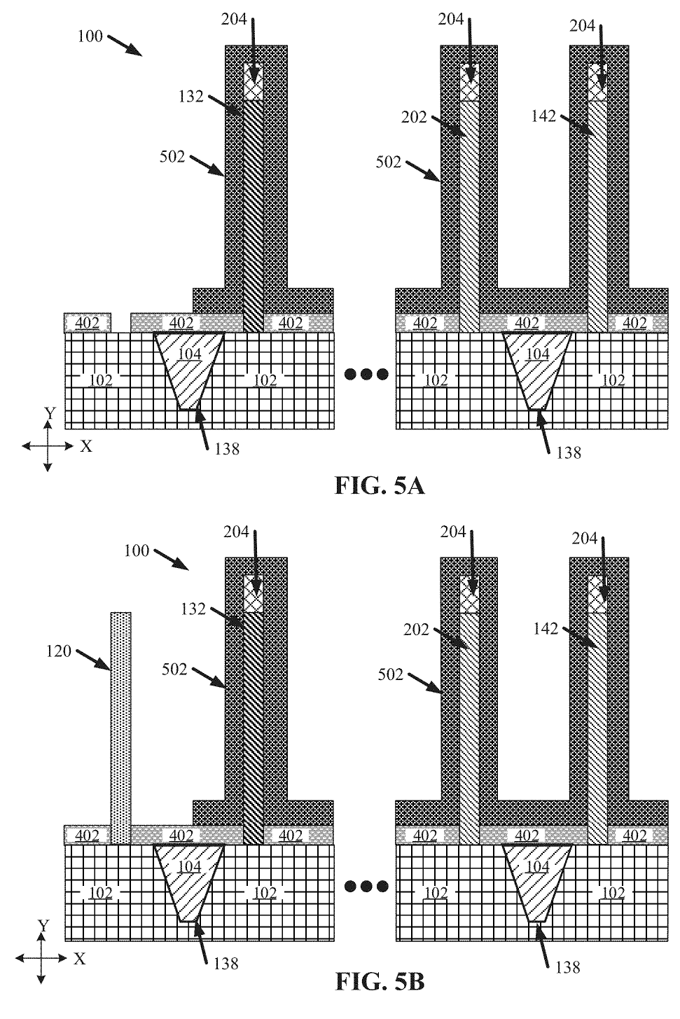

FIG. 5A illustrates a diagram of an example, non-limiting cross-sectional view of the vertical transport CMOS 100 during a seventh stage of manufacturing in accordance with one or more embodiments described herein. Repetitive description of like elements employed in other embodiments described herein is omitted for sake of brevity.

As shown in 5A, a block oxide cap 502 can be deposited (e.g., via sputtering, CVD, ALD, a combination thereof, and/or the like) over one or more of the conducting channels (e.g., the second conducting channel 132, the conducting channel comprising the conductive layer 202, and/or the fourth conducting channel 142) and/or one or more of the third spacer layers 402. Following deposition of the block oxide cap 502, one or more exposed conducting channels (e.g., one or more conducting channels not covered by the block oxide cap 502) can be removed. For example, the one or more conducting channels can be removed via a hot standard cleaning processes and/or a dry etching process (e.g., a hydrochloric acid etching). The block oxide cap 502 can resist the removal processes, thereby protecting the features upon which the block oxide cap 502 covers (e.g., the second conducting channel 132, the conducting channel comprising the conductive layer 202, and/or the fourth conducting channel 142). Additionally, the one or more third spacer layers 402 can resist the removal, thereby preserving the location of any removed conducting channels.

FIG. 5B illustrates a diagram of an example, non-limiting cross-sectional view of the vertical transport CMOS 100 during an eighth stage of manufacturing in accordance with one or more embodiments described herein. Repetitive description of like elements employed in other embodiments described herein is omitted for sake of brevity. As shown in FIG. 5B, the first conducting channel 120 can be deposited and/or grown (e.g., via CVD) upon one or more exposed portions of the semiconductor substrate 102. The one or more exposed portions of the semiconductor substrate 102 can correspond to the location of one or more conducting channels removed at the eighth stage of manufacturing. As described herein with regard to FIG. 1, the first conducting channel 120 can comprise an epitaxial material, wherein the crystal orientation of the semiconductor substrate 102 can facilitate vertical growth (e.g., along the “Y” axis) of the first conductive material to form the first conducting channel 120. For example, the first conducting channel 120 can be deposited and/or grown using selective-are metal-organic vapor phase epitaxy.

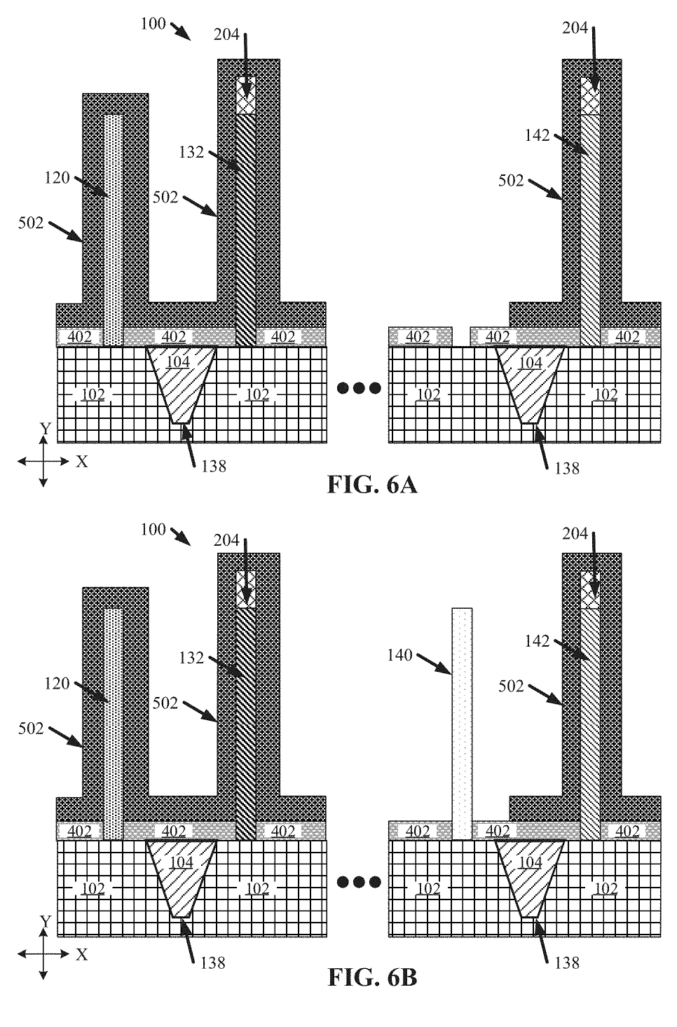

FIG. 6A illustrates a diagram of an example, non-limiting cross-sectional view of the vertical transport CMOS 100 during a ninth stage of manufacturing in accordance with one or more embodiments described herein. Repetitive description of like elements employed in other embodiments described herein is omitted for sake of brevity.

As shown in FIG. 6A, the block oxide cap 502 can be removed (e.g., via an etching process) from one or more conducting channels (e.g., the conducting channel comprising the conductive layer 202). Further, additional portions of the block oxide cap 502 can be deposited (e.g., via CVD and/or ALD) onto the one or more conducting channels deposited and/or grown at the ninth stage of manufacturing (e.g., first conducting channel 120). Thus, the location of the block oxide cap 502 can be adjusted at the tenth stage to facilitate selective removal of one or more conducting channels. Subsequent to the block oxide cap 502 adjustment, the one or more exposed conducting channels can be removed (e.g., via a standard cleaning processes and/or a dry etching process). However, the block oxide cap 502 and on or more of the third spacer layers 402 can resist the removal process, thereby preserving the location of the removed one or more conducting channels.

FIG. 6B illustrates a diagram of an example, non-limiting cross-sectional view of the vertical transport CMOS 100 during a tenth stage of manufacturing in accordance with one or more embodiments described herein. Repetitive description of like elements employed in other embodiments described herein is omitted for sake of brevity. As shown in FIG. 6B, the third conducting channel 140 can be deposited and/or grown (e.g., via CVD) upon one or more exposed portions of the semiconductor substrate 102. The one or more exposed portions of the semiconductor substrate 102 can correspond to the location of one or more conducting channels removed at the tenth stage of manufacturing. As described herein with regard to FIG. 1, the third conducting channel 140 can comprise an epitaxial material, wherein the crystal orientation of the semiconductor substrate 102 can facilitate vertical growth (e.g., along the “Y” axis) of the first conductive material to form the third conducting channel 140. For example, the third conducting channel 140 can be deposited and/or grown using selective-are metal-organic vapor phase epitaxy.

In various embodiments, the first conductive material deposited and/or grown at the eleventh stage of manufacturing can be characterized by a different concentration than that of the first conductive material deposited and/or grown at the ninth stage of manufacturing. For example, the first conductive material deposited and/or grown at the ninth stage of manufacturing can have a high concentration of a conductive element (e.g., indium) than the first conductive material deposited and/or grown at the eleventh stage of manufacturing.

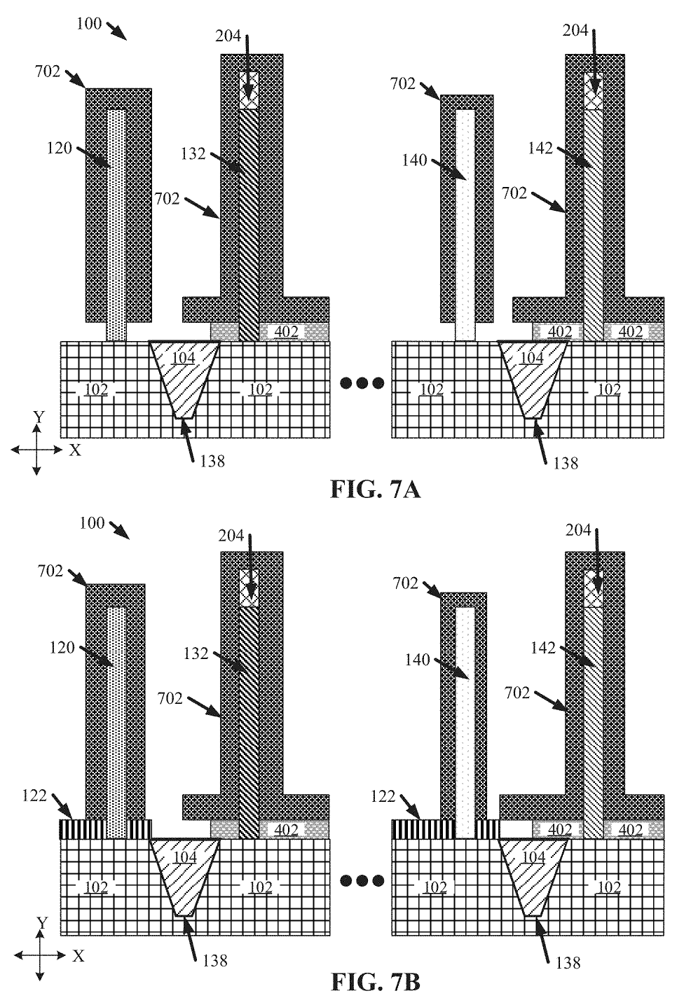

FIG. 7A illustrates a diagram of an example, non-limiting cross-sectional view of the vertical transport CMOS 100 during an eleventh stage of manufacturing in accordance with one or more embodiments described herein. Repetitive description of like elements employed in other embodiments described herein is omitted for sake of brevity.

Subsequent to the eleventh stage of manufacturing, the block oxide cap 502 can be removed (e.g., via a stripping and/or etching process); whereupon another oxide layer 702 can be deposited onto the various features of the vertical transport CMOS 100. The oxide layer 702 can be deposited via, for example, physical vapor deposition (“PVD”) such that the bottom-most portions of the oxide layer 702 (e.g., along the “Y” axis) are thinner than the other portions of the oxide layer 702. Thus, the portions of the oxide layer 702 (e.g., silicon oxide) that are adjacent to the one or more third spacer layers 402 can be thinner than portions of the oxide layer 702 that are adjacent to a conducting channel (e.g., first conducting channel 120, second conducting channel 132, third conducting channel 140, and/or fourth conducting channel 142). Thinning of the oxide layer 702 can facilitate removing (e.g., via RIE) portions of the oxide layer 702 that are adjacent to the one or more third spacer layers 402 and can correlate to one or more locations of the one or more first bottom S/D terminals 122.

Furthermore, as shown in FIG. 7A, portions of the one or more third spacer layers 402 that were adjacent to removed portions of the oxide layer 702 can also be removed (e.g., via a selective etching process, wherein the silicon nitride of the one or more third spacer layers 402 can be selective to silicon dioxide). As a result of the removal processes (e.g., one or more selective etching processes) at the twelfth stage of manufacturing, one or more portions of the semiconductor substrate 102 can be exposed from the oxide layer 702.

FIG. 7B illustrates a diagram of an example, non-limiting cross-sectional view of the vertical transport CMOS 100 during a twelfth stage of manufacturing in accordance with one or more embodiments described herein. Repetitive description of like elements employed in other embodiments described herein is omitted for sake of brevity. As shown in FIG. 7B, one or more first bottom S/D terminals 122 can be deposited onto the exposed regions of the semiconductor substrate 102 adjacent to one or more conducting channels (e.g., first conducting channel 120 and/or third conducting channel 140). For example, the one or more first bottom S/D terminals 122 can comprise epitaxial material which can be grown to mimic one or more crystalline characteristics of the semiconductor substrate 102.

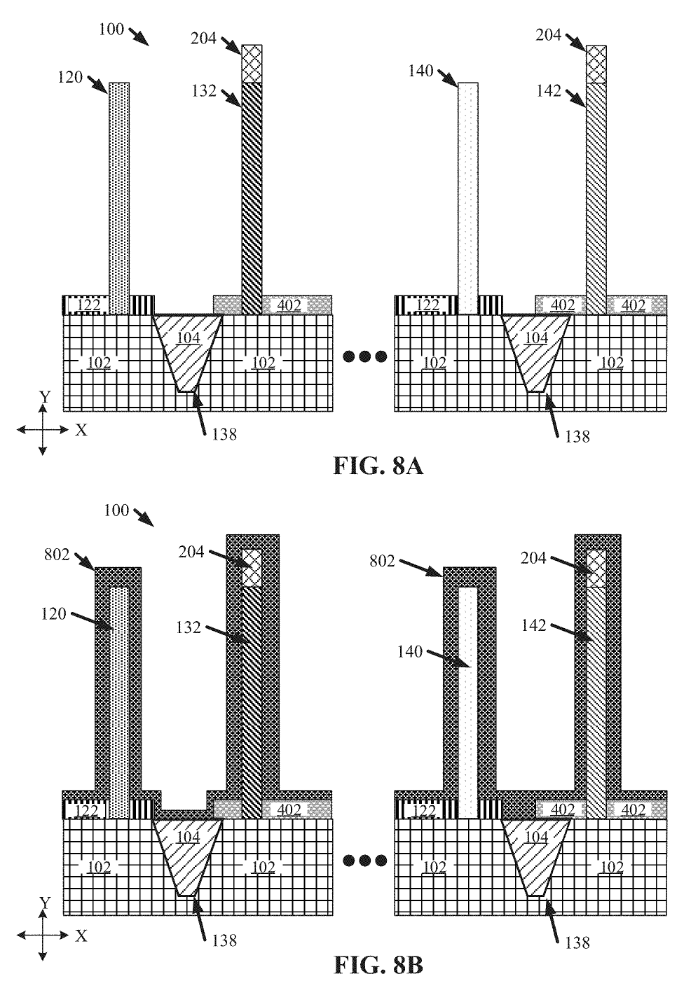

FIG. 8A illustrates a diagram of an example, non-limiting cross-sectional view of the vertical transport CMOS 100 during a thirteenth stage of manufacturing in accordance with one or more embodiments described herein. Repetitive description of like elements employed in other embodiments described herein is omitted for sake of brevity. As shown in FIG. 8A, the oxide layer 702 can be removed (e.g., via a selective etching process).

FIG. 8B illustrates a diagram of an example, non-limiting cross-sectional view of the vertical transport CMOS 100 during a fourteenth stage of manufacturing in accordance with one or more embodiments described herein. Repetitive description of like elements employed in other embodiments described herein is omitted for sake of brevity. As shown in FIG. 8B, a second oxide layer 802 can be deposited (e.g., via PVD) onto the various features of the vertical transport CMOS 100 (e.g., onto the plurality of conducting channels, the one or more first bottom S/D terminals 122, and/or the one or more third spacer layers 402. The second oxide layer 802 can be deposited such that portions of the second oxide layer 802 adjacent to the plurality of conducting channels are thicker than portions of the second oxide layer 802 adjacent to the one or more first bottom S/D terminals 122 and/or the one or more third spacer layers 402.

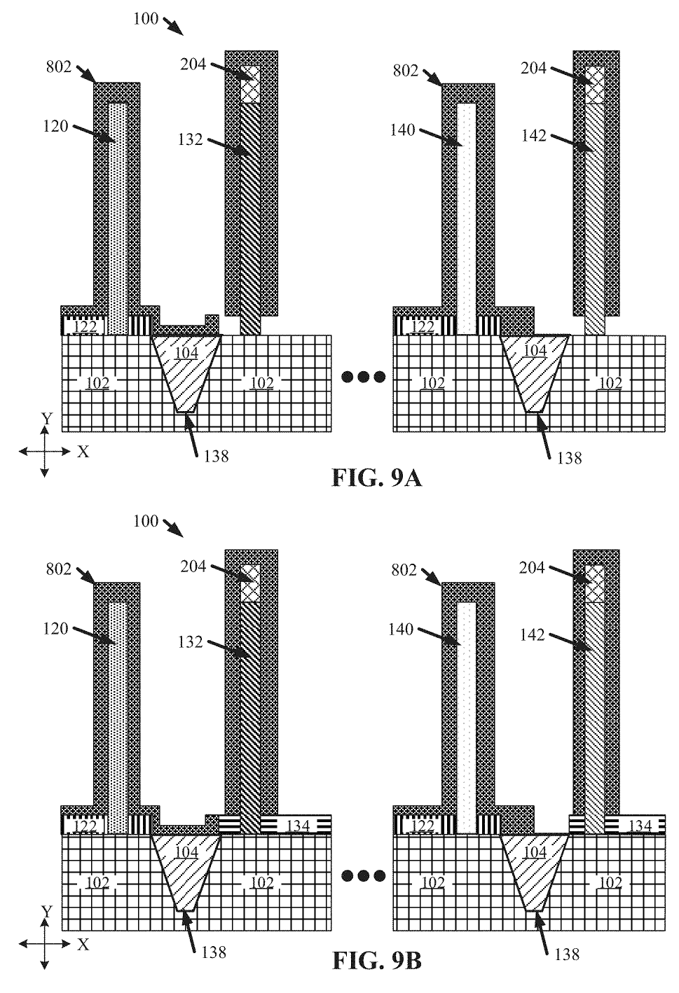

FIG. 9A illustrates a diagram of an example, non-limiting cross-sectional view of the vertical transport CMOS 100 during a fifteenth stage of manufacturing in accordance with one or more embodiments described herein. Repetitive description of like elements employed in other embodiments described herein is omitted for sake of brevity. As shown in FIG. 9A, one or more portions of the second oxide layer 802 that are adjacent to the one or more third spacer layers 402 can be removed (e.g., via spacer RIE). Further, subsequent to removing portions of the second oxide layer 802, the one or more remaining third spacer layers 402 can be removed (e.g., via selective etching). For example, one or more third spacer layers 402 adjacent to one or more conducting channels (e.g., second conducting channel 132 and/or fourth conducting channel 142) can be removed in preparation of forming the one or more second bottom S/D terminals 134.

FIG. 9B illustrates a diagram of an example, non-limiting cross-sectional view of the vertical transport CMOS 100 during a sixteenth stage of manufacturing in accordance with one or more embodiments described herein. Repetitive description of like elements employed in other embodiments described herein is omitted for sake of brevity. As shown in FIG. 9B, one or more second bottom S/D terminals 134 can be deposited onto the exposed regions of the semiconductor substrate 102 adjacent to one or more conducting channels (e.g., second conducting channel 132 and/or fourth conducting channel 142). For example, the one or more second bottom S/D terminals 134 can comprise epitaxial material which can be grown to mimic one or more crystalline characteristics of the semiconductor substrate 102.

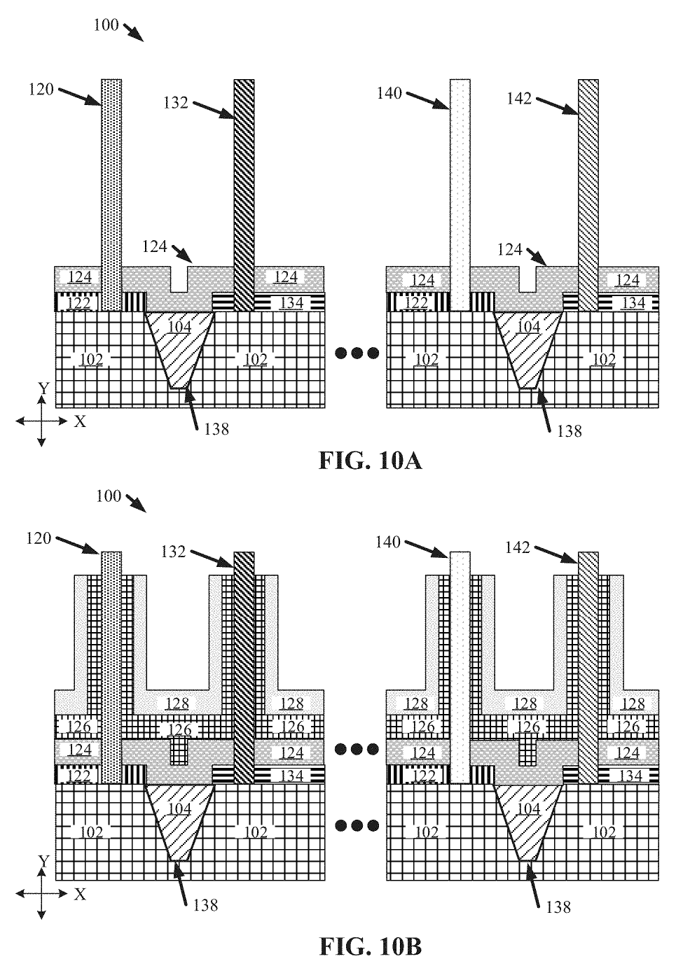

FIG. 10A illustrates a diagram of an example, non-limiting cross-sectional view of the vertical transport CMOS 100 during a seventeenth stage of manufacturing in accordance with one or more embodiments described herein. Repetitive description of like elements employed in other embodiments described herein is omitted for sake of brevity. As shown in FIG. 10A, the second oxide layer 802 and/or one or more portions of the hardmask layer 204 can be removed (e.g., stripped) from the vertical transport CMOS 100. Subsequent to said removal process, the first spacer layer 124 can be deposited (e.g., via HDP CVD) onto the one or more first bottom S/D terminals 122, the one or more shallow trenches 138, and/or the one or more second bottom S/D terminals 134.

FIG. 10B illustrates a diagram of an example, non-limiting cross-sectional view of the vertical transport CMOS 100 during an eighteenth stage of manufacturing in accordance with one or more embodiments described herein. Repetitive description of like elements employed in other embodiments described herein is omitted for sake of brevity. As shown in FIG. 10B, a metal dielectric gate (e.g., comprising the gate dielectric layer 126 and/or the metal layer 128) can be deposited onto the first spacer layer 124 and/or adjacent to the plurality of conducting channels (e.g., first conducting channel 120, second conducting channel 132, third conducting channel 140, and/or fourth conducting channel 142). In one or more embodiments, the nineteenth stage of manufacturing can further comprise a subsequent oxide deposition followed by an oxide recess and a chamfering of the metal dielectric gate. Further, in various embodiments, the metal dielectric gate does not fully extend to the respective distal ends of the plurality of conducting channels (e.g., as shown in FIG. 10B).

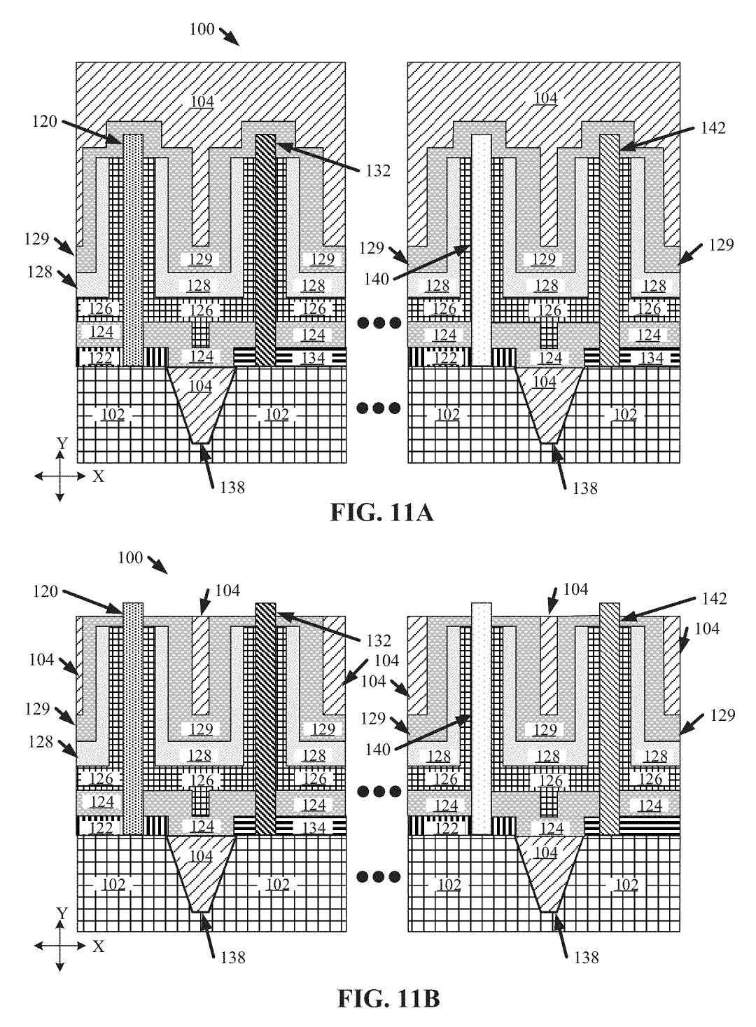

FIG. 11A illustrates a diagram of an example, non-limiting cross-sectional view of the vertical transport CMOS 100 during a nineteenth stage of manufacturing in accordance with one or more embodiments described herein. Repetitive description of like elements employed in other embodiments described herein is omitted for sake of brevity. As shown in FIG. 11A, the second spacer layer 129 can be deposited (e.g., via HDP CVD) onto the metal dielectric gate and/or the plurality of conducting channels. Further, the dielectric layer 104 can be blanket deposited onto the second spacer layer 129.

FIG. 11B illustrates a diagram of an example, non-limiting cross-sectional view of the vertical transport CMOS 100 during a twentieth stage of manufacturing in accordance with one or more embodiments described herein. Repetitive description of like elements employed in other embodiments described herein is omitted for sake of brevity. As shown in FIG. 11B, the second spacer layer 129 and/or the dielectric layer 104 can be subjected to chemical-mechanical planarization (“CMP”). The CMP can expose respective active sites at the distal ends of the plurality of conducting channels to contact the one or more first top S/D terminals 130 and/or second top S/D terminals 136.

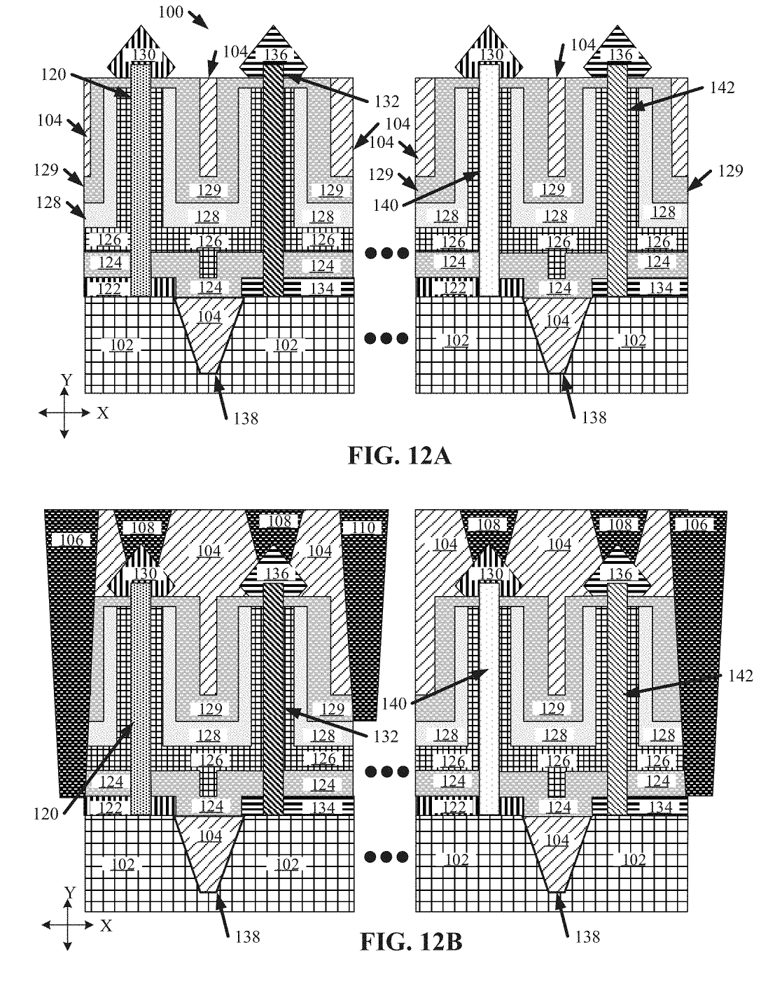

FIG. 12A illustrates a diagram of an example, non-limiting cross-sectional view of the vertical transport CMOS 100 during a twenty-first stage of manufacturing in accordance with one or more embodiments described herein. Repetitive description of like elements employed in other embodiments described herein is omitted for sake of brevity. As shown in FIG. 12A, one or more first top S/D terminals 130 and/or one or more second top S/D terminals 136 can be deposited and/or grown onto the exposed regions of the plurality of conducting channels (e.g., respective distal ends of the plurality of conducting channels). For example, the one or more first top S/D terminals 130 and/or the one or more second top S/D terminals 136 can comprise epitaxial material.

FIG. 12B illustrates a diagram of an example, non-limiting cross-sectional view of the vertical transport CMOS 100 during a twenty-second stage of manufacturing in accordance with one or more embodiments described herein. Repetitive description of like elements employed in other embodiments described herein is omitted for sake of brevity. As shown in FIG. 12B, the one or more bottom S/D contacts 106, the one or more top S/D contacts 108, and/or the one or more gate contacts 110 can be deposited (e.g., via one or more middle-of-the-line (“MOL”) processes) onto the vertical transport CMOS 100. Further, the dielectric layer 104 can be blanket deposited (e.g., via CVD) adjacent to: the one or more bottom S/D contacts 106, the one or more top S/D contacts 108, the one or more gate contacts 110, the one or more first top S/D terminals 130, the one or more second top S/D terminals 136, and/or the second spacer layer 129. Furthermore, to reach the structure shown in FIG. 1, the dielectric layer 104 is extended (e.g., via a wet etch and/or RIE) along the “Y” axis towards the semiconductor substrate 102 to: separate the metal dielectric gate from the one or more bottom S/D contacts 106, and/or separate a portion of the metal dielectric gate comprised within one finFET (e.g., first finFET 112) from a portion of the metal dielectric gate comprised within an adjacent finFET (e.g., second finFET 114).

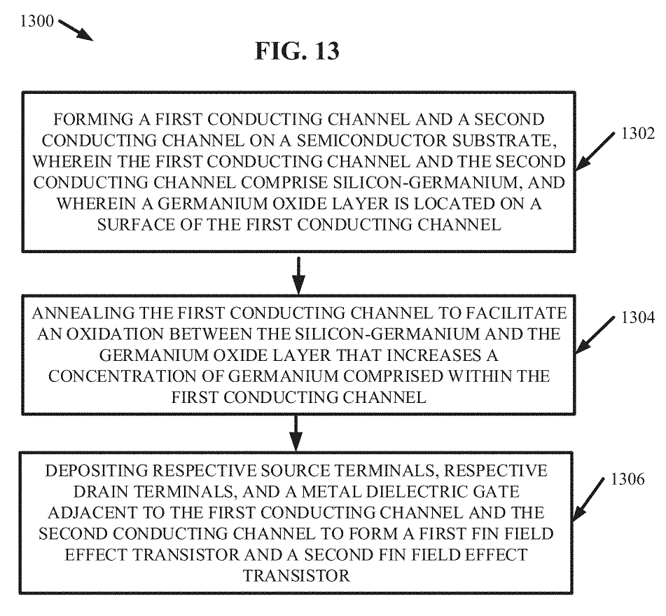

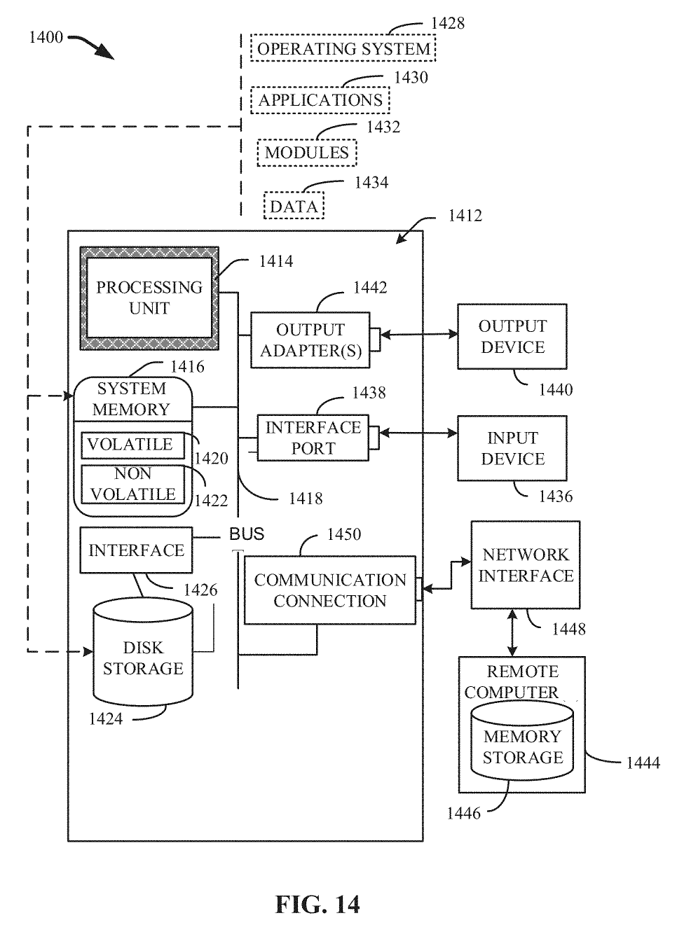

FIG. 13 illustrates a flow diagram of an example, non-limiting method 1300 that can facilitate manufacturing the vertical transport CMOS 100 in accordance with one or more embodiments described herein. Repetitive description of like elements employed in other embodiments described herein is omitted for sake of brevity. In one or more embodiments, the method 1300 can correlate to the manufacturing steps illustrated and/or described with regard to FIGS. 2A-12B.

At 1302, the method 1300 can comprise forming plurality of conducting channels on a semiconductor substrate 102 (e.g., silicon <111>). For example, 1302 can comprise forming a conducting channel comprising conductive layer 202 and/or the fourth conducting channel 142 on the semiconductor substrate 102. For instance, the formed conducting channels can comprise silicon-germanium. Additionally, the germanium oxide layer 304 can be located on a surface of one of the conducting channels (e.g., a conducting channel comprising the conductive layer 202). The forming at 1302 can correlate to the illustrations and/or descriptions provided herein with regard to FIGS. 2A-3A.

At 1304, the method 1300 can also comprise annealing the conducting channel coated with the germanium oxide layer 304 to facilitate an oxidation between the silicon-germanium comprised within the conducting channel and the germanium oxide layer 304 that can increase a concentration of germanium comprised within the subject conducting channel. For example, the annealing at 1304 can correlate to the illustrations and/or descriptions provided herein with regard to FIG. 3B.

At 1306, the method 1300 can further comprise depositing respective source terminals (e.g., one or more first bottom S/D terminals 122 and/or one or more second bottom S/D terminals 134), respective drain terminals (e.g., one or more first top S/D terminals 130 and/or one or more second top S/D terminals 136), and/or the metal dielectric gate (e.g., comprising gate dielectric layer 126 and/or metal layer 128) adjacent to the plurality of conducting channels formed at 1302. The depositing at 1306 can form a plurality of finFETs, such as second finFET 114 and/or fourth finFET 118. Furthermore, the depositing at 1306 can correlate to the illustrates and/or descriptions provided herein with regard to FIGS. 4A-12B.

In one or more embodiments, the method 1300 can comprise forming the first conducting channel 120 on the semiconductor substrate 102. For example, the first conducting channel 120 can comprise an element other than germanium selected from a group consisting of periodic table group thirteen, periodic table group fourteen and periodic table group fifteen. For example, forming the first conducting channel 120 can be implemented in accordance with the illustrations and/or descriptions provided herein with regard to FIGS. 4A-5B. Further, the depositing at 1306 can further comprise depositing the respective source terminals, the respective drain terminals, and the metal gate adjacent to the first conducting channel 120 to form the first finFET 112; for example, in accordance with the illustrations and/or descriptions provided herein with regard to FIGS. 7A-12B.

Additionally, in various embodiments, the method 1300 can further comprise forming the third conducting channel 140 on the semiconductor substrate 102. For example, the third conducting channel 140 can comprise an element other than germanium selected from a group consisting of periodic table group thirteen, periodic table group fourteen and periodic table group fifteen. For instance, the third conducting channel 140 can comprise the same conductive material as the first conducting channel 120. However, the first conducting channel 120 can have a greater concentration of the conductive material (e.g., indium) than the third conducting channel 140. For example, forming the third conducting channel 140 can be implemented in accordance with the illustrations and/or descriptions provided herein with regard to FIGS. 6A-6B. Further, the depositing at 1306 can further comprise depositing the respective source terminals, the respective drain terminals, and the metal gate adjacent to the third conducting channel 140 to form the third finFET 116; for example, in accordance with the illustrations and/or descriptions provided herein with regard to FIGS. 7A-12B.

In order to provide a context for the various aspects of the disclosed subject matter, FIG. 10 as well as the following discussion are intended to provide a general description of a suitable environment in which the various aspects of the disclosed subject matter can be implemented. FIG. 10 illustrates a block diagram of an example, non-limiting operating environment in which one or more embodiments described herein can be facilitated. Repetitive description of like elements employed in other embodiments described herein is omitted for sake of brevity. With reference to FIG. 10, a suitable operating environment 1400 for implementing various aspects of this disclosure can include a computer 1412. The computer 1412 can also include a processing unit 1414, a system memory 1416, and a system bus 1418. The system bus 1418 can operably couple system components including, but not limited to, the system memory 1416 to the processing unit 1414. The processing unit 1414 can be any of various available processors. Dual microprocessors and other multiprocessor architectures also can be employed as the processing unit 1414. The system bus 1418 can be any of several types of bus structures including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Firewire, and Small Computer Systems Interface (SCSI). The system memory 1416 can also include volatile memory 1420 and nonvolatile memory 1422. The basic input/output system (BIOS), containing the basic routines to transfer information between elements within the computer 1412, such as during start-up, can be stored in nonvolatile memory 1422. By way of illustration, and not limitation, nonvolatile memory 1422 can include read only memory (ROM), programmable ROM (PROM), electrically programmable ROM (EPROM), electrically erasable programmable ROM (EEPROM), flash memory, or nonvolatile random access memory (RAM) (e.g., ferroelectric RAM (FeRAM). Volatile memory 1420 can also include random access memory (RAM), which acts as external cache memory. By way of illustration and not limitation, RAM is available in many forms such as static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM.

Computer 1412 can also include removable/non-removable, volatile/non-volatile computer storage media. FIG. 10 illustrates, for example, a disk storage 1424. Disk storage 1424 can also include, but is not limited to, devices like a magnetic disk drive, floppy disk drive, tape drive, Jaz drive, Zip drive, LS-100 drive, flash memory card, or memory stick. The disk storage 1424 also can include storage media separately or in combination with other storage media including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage 1424 to the system bus 1418, a removable or non-removable interface can be used, such as interface 1426. FIG. 10 also depicts software that can act as an intermediary between users and the basic computer resources described in the suitable operating environment 1400. Such software can also include, for example, an operating system 1428. Operating system 1428, which can be stored on disk storage 1424, acts to control and allocate resources of the computer 1412. System applications 1430 can take advantage of the management of resources by operating system 1428 through program modules 1432 and program data 1434, e.g., stored either in system memory 1416 or on disk storage 1424. It is to be appreciated that this disclosure can be implemented with various operating systems or combinations of operating systems. A user enters commands or information into the computer 1412 through one or more input devices 1436. Input devices 1436 can include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices can connect to the processing unit 1414 through the system bus 1418 via one or more interface ports 1438. The one or more Interface ports 1438 can include, for example, a serial port, a parallel port, a game port, and a universal serial bus (USB). One or more output devices 1440 can use some of the same type of ports as input device 1436. Thus, for example, a USB port can be used to provide input to computer 1412, and to output information from computer 1412 to an output device 1440. Output adapter 1442 can be provided to illustrate that there are some output devices 1440 like monitors, speakers, and printers, among other output devices 1440, which require special adapters. The output adapters 1442 can include, by way of illustration and not limitation, video and sound cards that provide a means of connection between the output device 1440 and the system bus 1418. It should be noted that other devices and/or systems of devices provide both input and output capabilities such as one or more remote computers 1444.

Computer 1412 can operate in a networked environment using logical connections to one or more remote computers, such as remote computer 1444. The remote computer 1444 can be a computer, a server, a router, a network PC, a workstation, a microprocessor based appliance, a peer device or other common network node and the like, and typically can also include many or all the elements described relative to computer 1412. For purposes of brevity, only a memory storage device 1446 is illustrated with remote computer 1444. Remote computer 1444 can be logically connected to computer 1412 through a network interface 1448 and then physically connected via communication connection 1450. Further, operation can be distributed across multiple (local and remote) systems. Network interface 1448 can encompass wire and/or wireless communication networks such as local-area networks (LAN), wide-area networks (WAN), cellular networks, etc. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL). One or more communication connections 1450 refers to the hardware/software employed to connect the network interface 1448 to the system bus 1418. While communication connection 1450 is shown for illustrative clarity inside computer 1412, it can also be external to computer 1412. The hardware/software for connection to the network interface 1448 can also include, for exemplary purposes only, internal and external technologies such as, modems including regular telephone grade modems, cable modems and DSL modems, ISDN adapters, and Ethernet cards.

Embodiments of the present invention can be a system, a method, an apparatus and/or a computer program product at any possible technical detail level of integration. The computer program product can include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can include copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of various aspects of the present invention can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to customize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein includes an article of manufacture including instructions which implement aspects of the function/act specified in the flowchart and/or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams can represent a module, segment, or portion of instructions, which includes one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer and/or computers, those skilled in the art will recognize that this disclosure also can or can be implemented in combination with other program modules. Generally, program modules include routines, programs, components, data structures, etc. that perform particular tasks and/or implement particular abstract data types. Moreover, those skilled in the art will appreciate that the inventive computer-implemented methods can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments where tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to and/or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit or device including, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components including a memory. It is to be appreciated that memory and/or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems, computer program products and computer-implemented methods. It is, of course, not possible to describe every conceivable combination of components, products and/or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An apparatus, comprising:
a semiconductor substrate;
a first conducting channel comprising a first concentration of a first element, wherein the first conducting channel extends from the semiconductor substrate, and wherein the first element is germanium;
a second conducting channel comprising a second concentration of the first element, wherein the second conducting channel extends from the semiconductor substrate, and wherein the first concentration is greater than the second concentration; and
a metal dielectric gate adjacent to the first conducting channel and the second conducting channel, wherein the metal dielectric gate comprises a gate dielectric layer and a metal layer.

2. The apparatus of claim 1, further comprising:
a third conducting channel extending from the semiconductor substrate, wherein the third conducting channel comprises a second element selected from a group consisting of periodic table group thirteen, periodic table group fourteen and periodic table group fifteen, and wherein the metal dielectric gate is further adjacent to the third conducting channel.

3. The apparatus of claim 2, further comprising:
a fourth conducting channel extending from the semiconductor substrate, wherein the fourth conducting channel comprises the second element, wherein the third conducting channel has a greater concentration of the second element than the fourth conducting channel.

4. The apparatus of claim 3, wherein the semiconductor substrate comprises silicon having a crystal orientation comprising atoms on three planes.

5. The apparatus of claim 4, wherein the third conducting channel and the fourth conducting channel comprise indium, gallium and arsenic.

6. The apparatus of claim 5, wherein the third conducting channel has a greater concentration of indium than the fourth conducting channel.

7. The apparatus of claim 6, wherein the first conducting channel and the second conducting channel have a first type of conductivity, and wherein the third conducting channel and the fourth conducting channel have a second type of conductivity.

8. The apparatus of claim 7, wherein the first conducting channel and the metal dielectric gate are comprised within a first fin field effect transistor of the first type of conductivity, wherein the second conducting channel and the metal dielectric gate are comprised within a second fin field effect transistor of the first type of conductivity, wherein the third conducting channel and the metal dielectric gate are comprised within a third fin field effect transistor of the second type of conductivity, and wherein the fourth conducting channel and the metal dielectric gate are comprised within a fourth fin field effect transistor of the second type of conductivity.

9. The apparatus of claim 8, wherein a threshold voltage of the third fin field effect transistor is lower than a threshold voltage of the first fin field effect transistor, wherein the threshold voltage of the first fin field effect transistor is lower than a threshold voltage of the fourth fin field effect transistor, and wherein the threshold voltage of the fourth fin field effect transistor is lower than a threshold voltage of the second fin field effect transistor.

10. The apparatus of claim 9, wherein a dielectric constant of the metal dielectric gate is greater than a dielectric constant of silicon oxide.

11. A method, comprising:
forming a first conducting channel and a second conducting channel on a semiconductor substrate, wherein the first conducting channel and the second conducting channel comprise silicon-germanium, and wherein a germanium oxide layer is located on a surface of the first conducting channel;
annealing the first conducting channel to facilitate an oxidation between the silicon-germanium and the germanium oxide layer that increases a concentration of germanium comprised within the first conducting channel; and
depositing respective source terminals, respective drain terminals, and a metal dielectric gate adjacent to the first conducting channel and the second conducting channel to form a first fin field effect transistor and a second fin field effect transistor.

12. The method of claim 11, further comprising:
forming a third conducting channel on the semiconductor substrate, wherein the third conducting channel comprises an element of than germanium selected from a group consisting of periodic table group thirteen, periodic table group fourteen and periodic table group fifteen, wherein the depositing further comprises depositing the respective source terminals, the respective drain terminals, and the metal dielectric gate adjacent to the third conducting channel to form a third fin field effect transistor.

13. The method of claim 12, further comprising:
forming a fourth conducting channel on the semiconductor substrate, wherein the fourth conducting channel comprises the element, wherein the third conducting channel has a greater concentration of the element than the fourth conducting channel, and wherein the depositing further comprises depositing the respective source terminals, the respective drain terminals, and the metal dielectric gate adjacent to the fourth conducting channel to form a fourth fin field effect transistor.

14. The method of claim 13, wherein the semiconductor substrate comprises silicon having a crystal orientation comprising atoms on three planes.

15. The method of claim 14, wherein the third conducting channel and the fourth conducting channel comprise indium, gallium and arsenic, and wherein the third conducting channel has a greater concentration of indium than the fourth conducting channel.

16. The method of claim 15, wherein a threshold voltage of the third fin field effect transistor is lower than a threshold voltage of the first fin field effect transistor, wherein the threshold voltage of the first fin field effect transistor is lower than a threshold voltage of the fourth fin field effect transistor, and wherein the threshold voltage of the fourth fin field effect transistor is lower than a threshold voltage of the second fin field effect transistor.

17. An apparatus comprising:
a semiconductor substrate;
a first conducting channel comprising a first element, wherein the first conducting channel extends from the semiconductor substrate, and wherein the first element is germanium;
a second conducting channel comprising a second element, wherein the second conducting channel extends from the semiconductor substrate, and wherein the second element is selected from a group consisting of periodic table group thirteen, periodic table group fourteen and periodic table group fifteen; and
a metal dielectric gate adjacent to the first conducting channel and the second conducting channel, wherein the metal dielectric gate comprises a gate dielectric layer and a metal layer.

18. The apparatus of claim 17, further comprising:
a third conducting channel comprising the first element, wherein the third conducting channel extends from the semiconductor substrate, and wherein the first conducting channel has a greater concentration of the first element than the third conducting channel.

19. The apparatus of claim 18, further comprising:
a fourth conducting channel comprising the second element, wherein the fourth conducting channel extends from the semiconductor substrate, and wherein the second conducting channel has a greater concentration of the second element than the fourth conducting channel.

20. The apparatus of claim 17, wherein the first conducting channel and the metal dielectric gate are comprised within a first fin field effect transistor, wherein the second conducting channel and the metal dielectric gate are comprised within a second fin field effect transistor, and wherein a threshold voltage of the first fin field effect transistor is higher than a threshold voltage of the second fin field effect transistor.
